(19) United States
(12) Patent Application Publication
(10) Pub. No.: US 2009/0052237 A1
(43) Pub. Date: Feb. 26, 2009

(54) MAGNETIC MEMORY DEVICE AND MAGNETIC MEMORY APPARATUS

(76) Inventors: Hirofumi Morise, Kanagawa-ken (JP); Shiho Nakamura, Kanagawa-ken (JP); Satoshi Yanagi, Kanagawa-ken (JP); Yuichi Ohsawa, Kanagawa-ken (JP); Daisuke Saida, Tokyo (JP)

Correspondence Address: NIXON & VANDERHYE, PC, 901 NORTH GLEBE ROAD, 11TH FLOOR, ARLINGTON, VA, 22203, US

(21) Appl. No.: 12/107,127

(22) Filed: Apr. 22, 2008

(30) Foreign Application Priority Data
Aug. 22, 2007 (JP) 2007-215593

(51) Int. Cl. G11C 11/00; H01L 29/82

(52) U.S. Cl. 365/171; 257/421; 257/E29.323

(57) ABSTRACT

A magnetic memory element includes a laminated construction of a first electrode, a first pinned layer, a first intermediate layer, a memory layer, a second intermediate layer, a second pinned layer and a second electrode, and a third electrode coupled to the first intermediate layer and not directly coupled to the memory layer. The magnetization directions of the first pinned layer, the second pinned layer, and the memory layer are parallel or antiparallel to each other. The magnetization direction of the memory layer takes a first direction when the current is passed with a first polarity so that the current flowing through the first pinned layer exceeds a first threshold. The magnetization direction of the memory layer takes a second direction when the current is passed with a second polarity so that the current flowing through the first pinned layer exceeds a second threshold.

### CROSS-REFERENCE TO RELATED APPLICATIONS

This application is based upon and claims the benefit of priority from the prior Japanese Patent Application No. 2007-215593, filed on Aug. 22, 2007; the entire contents of which are incorporated herein by reference.

### BACKGROUND OF THE INVENTION

1. Field of the Invention

This invention relates to a magnetic memory device and a magnetic memory apparatus based thereon.

2. Background Art

Recently, there has been a growing demand for information processing devices that meet various needs as an underpinning and an engine for the extensively and highly advanced information society. In particular, hard disk drives and magnetic random access memories (MRAM) are memory devices based on the magnetic moment of ferromagnets. Such spin-electronics devices using the spin degree of freedom of electrons are characterized in being suitable to increasing integration by downsizing cells, operable at high speed, and nonvolatile. Hence their use will further expand in memory apparatuses and other applications.

In one method for controlling the magnetization direction of small magnetic bodies in spin-electronics devices, the current-induced spin transfer phenomenon is used. The “spin transfer” refers to the transfer of angular momentum from the spin of conduction electrons to the localized magnetic moment of the magnetic bodies. In contrast to the scheme based on magnetic field application, the spin transfer scheme is characterized in that the write current can be reduced with the downsizing of cells.

For example, a lamination film composed of a magnetization-pinned magnetic layer (hereinafter also referred to as “pinned layer”), an intermediate layer, and a magnetization-free magnetic layer (hereinafter also referred to as “memory layer”) is patterned with dots, each being tens to hundreds of nanometers square. By passing a current through this lamination film in the direction perpendicular to the film plane, the magnetization direction can be controlled (written) and detected (read), and can be used for a memory device.

In order to enhance the reading efficiency of such a magnetic device based on spin transfer writing, the intermediate layer can be made of an insulative thin film to use the tunneling magnetoresistance effect.

However, in a magnetic memory device characterized by magnetization reversal by spin transfer torque, passing a current through a layer made of an insulator results in increased power consumption, and passing a large current may result in device breakdown.

To avoid this, it is considered to use a structure in which electrodes and interconnects are coupled to the memory layer to separate the current path at the time of writing from the current path at the time of reading. However, the structure in which another conductive layer is provided on the side surface of the memory layer and coupled thereto may cause variation in the shape of the memory layer in the manufacturing process. This leads to increased manufacturing cost, and hence is impractical.

On the other hand, U.S. Pat. No. 6,980,469 (hereinafter referred to as Patent Document 1) discloses a magnetic device having a pinned layer and a memory layer laminated via a nonmagnetic layer. The magnetization direction of the pinned layer is perpendicular to its major surface, and the magnetization direction of the memory layer is parallel to its surface. Patent Document 1 discloses a method for controlling the magnetization direction of the memory layer by the polarity of a current pulse flowing through the nonmagnetic layer and the pinned layer. However, in this case, the current pulse needs to be controlled with high precision, hence leaving room for improvement.

Theoretical models of the spin state of electrons flowing through a laminated film made of a magnetic layer and a nonmagnetic layer and the magnetization reversal of a magnetic material by spin torque transfer are disclosed in: A. Brataas et al., Phys. Rev. Lett. 84, 2481 (2000) (hereinafter referred to as Non-Patent Document 1); and T. Valet and A. Fert, Phys. Rev. B 48, 7099 (1993) (hereinafter referred to as Non-Patent Document 2).

### SUMMARY OF THE INVENTION

According to an aspect of the invention, there is provided a magnetic memory device including: a first pinned layer including a ferromagnetic material and having a fixed magnetization direction; a second pinned layer including a ferromagnetic material and having a fixed magnetization direction; a memory layer provided between the first pinned layer and the second pinned layer, including a ferromagnetic material, and having a variable magnetization direction; a first intermediate layer provided between the first pinned layer and the memory layer and made of a nonmagnetic material; a second intermediate layer provided between the second pinned layer and the memory layer and made of a nonmagnetic material; a first electrode coupled to the first pinned layer; a second electrode coupled to the second pinned layer; and a third electrode coupled to the first intermediate layer and not directly coupled to the memory layer, the magnetization directions of the first pinned layer, the second pinned layer, and the memory layer being parallel or antiparallel to each other; a current being able to be passed in both directions between the first electrode and the third electrode, the magnetization direction of the memory layer taking a first direction when the current is passed with a first polarity so that a current flowing through the first pinned layer to exceeds a first threshold, and the magnetization direction of the memory layer taking a second direction when the current is passed with a second polarity so that a current flowing through the first pinned layer to exceeds a second threshold.

According to another aspect of the invention, there is provided a magnetic memory apparatus including: a plurality of word lines; a plurality of write bit lines; a plurality of read bit lines; and a plurality of magnetic memory devices, each of the magnetic memory devices including; a first pinned layer including a ferromagnetic material and having a fixed magnetization direction; a second pinned layer including a ferromagnetic material and having a fixed magnetization direction; a memory layer provided between the first pinned layer and the second pinned layer, including a ferromagnetic material, and having a variable magnetization direction; a first intermediate layer provided between the first pinned layer and the memory layer and made of a nonmagnetic material; a second intermediate layer provided between the second pinned layer and the memory layer and made of a nonmagnetic material; a first electrode coupled to the first pinned layer; a second electrode coupled to the second pinned layer; and a third electrode coupled to the first intermediate layer and not directly coupled to the memory layer, the magnetization directions of the first pinned layer, the second pinned layer, and the memory layer being parallel or antiparallel to each other, a current being able to be passed in both directions between the first electrode and the third electrode, the magnetization direction of the memory layer taking a first direction when the current is passed with a first polarity so that a current flowing through the first pinned layer to exceeds a first threshold, and the magnetization direction of the memory layer taking a second direction when the current is passed with a second polarity so that a current flowing through the first pinned layer to exceeds a second threshold, one of the plurality of word lines and one of the plurality of write bit lines being selected being configured to pass a current between the first electrode and the third electrode of one of the plurality of the magnetic memory devices, thereby allowing the magnetization direction of the memory layer thereof to take one of the first direction and the second direction, and one of the plurality of word lines and one of the plurality of read bit lines being selected being configured to pass a current between the second electrode and the first electrode of one of the plurality of the magnetic memory devices, or to pass a current between the second electrode and the third electrode thereof, thereby allowing detection of a magnetoresistance effect between the memory layer and the second pinned layer.

### BRIEF DESCRIPTION OF THE DRAWINGS

FIG. 1 is a schematic view showing a magnetic memory element according to a first embodiment of the invention.

FIG. 2 is a graph illustrating exchange coupling between two ferromagnetic layers through a nonmagnetic layer.

FIG. 3 is a schematic view showing a magnetic memory element according to a second embodiment of the invention.

FIG. 4 is a schematic view showing a magnetic memory element according to a third embodiment of the invention.

FIG. 5 is a schematic view showing a magnetic memory element according to a fourth embodiment of the invention.

FIG. 6 is a schematic view showing a magnetic memory element according to a fifth embodiment of the invention.

FIG. 7 is a graph illustrating a calculated result of the reversal current threshold.

FIG. 8 is a schematic view showing a magnetic memory element according to a sixth embodiment of the invention.

FIG. 9 is a schematic view showing a magnetic memory element according to a seventh embodiment of the invention.

FIG. 10 is a schematic view showing a magnetic memory element according to an eighth embodiment of the invention.

FIG. 11 is a schematic view showing a magnetic memory element according to a ninth embodiment of the invention.

FIG. 12 is a schematic view showing a magnetic memory element according to a tenth embodiment of the invention.

FIG. 13 is a schematic view showing a magnetic memory element according to an eleventh embodiment of the invention.

FIG. 14 is a schematic view of a twelfth embodiment of the magnetic memory apparatus of the invention.

FIG. 15 shows a schematic view showing each memory cell of a magnetic memory apparatus according to a twelfth embodiment of the invention.

FIGS. 16A and 16B schematically show the cross-sectional structure of a magnetic memory apparatus according to a twelfth embodiment of the invention.

FIG. 17 shows a schematic view showing each memory cell of a magnetic memory apparatus according to a thirteenth embodiment of the invention.

FIGS. 18A and 18B schematically show the cross-sectional structure of a magnetic memory apparatus according to a thirteenth embodiment of the invention.

FIGS. 19A and 19B schematically show each memory cell of a magnetic memory apparatus according to a fourteenth and 1 fourteenth embodiment of the invention, respectively.

FIGS. 20A and 20B schematically show each memory cell of a magnetic memory apparatus according to a sixteenth and a seventeenth embodiment of the invention, respectively.

### DETAILED DESCRIPTION OF THE INVENTION

Embodiments of the invention will now be described in detail with reference to the drawings.

### FIRST EMBODIMENT

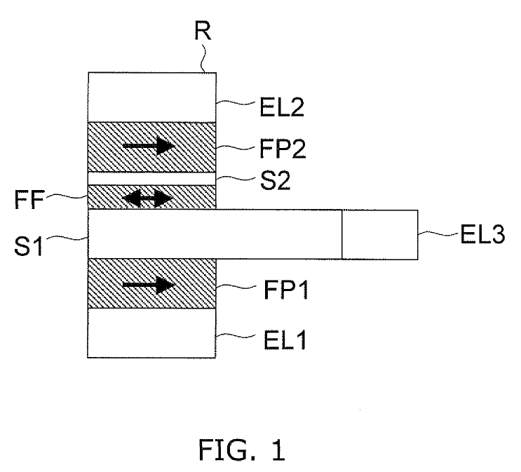

FIG. 1 schematically shows the cross-sectional structure of a magnetic memory device according to a first embodiment of the invention.

The magnetic memory device R has a structure in which a ferromagnetic layer FP1, a nonmagnetic layer S1, a ferromagnetic layer FF, a nonmagnetic layer S2, and a ferromagnetic layer FP2 are laminated in this order on a substrate with or without the intermediary of a nonmagnetic layer. The planar shape of the magnetic memory device R is illustratively a quadrangle, in which case the three-dimensional shape of the device can be a combination of a quadrangular prism and a truncated quadrangular pyramid. The ferromagnetic layers FP1, FP2, and FF may have a laminated structure composed of a plurality of sublayers as described later. However, a description is first given of an example where the ferromagnetic layers FP1, FP2, and FF are monolayers.

The magnetization direction of the ferromagnetic layer FP1 is pinned. This can be realized, for example, by providing an antiferromagnetic layer AF1 on the surface of the ferromagnetic layer FP1 opposite to the nonmagnetic layer S1, although not shown in FIG. 1. Alternatively, it can be realized by forming the ferromagnetic layer FP1 from a magnetic material having a very high uniaxial anisotropy constant Ku. The ferromagnetic layer FP1 is hereinafter referred to as “first pinned layer FP1”.

The magnetization direction of the ferromagnetic layer FP2 is also pinned. This can also be realized, for example, by providing an antiferromagnetic layer AF2 on the surface of the ferromagnetic layer FP2 opposite to the nonmagnetic layer S2, although not shown in FIG. 1. Alternatively, it can also be realized by forming the ferromagnetic layer FP2 from a magnetic material having a very high uniaxial anisotropy constant Ku. The ferromagnetic layer FP2 is hereinafter referred to as “second pinned layer FP2”.

With regard to the magnetization direction of the ferromagnetic layer FF, such pinning mechanism is not provided. Hence the ferromagnetic layer FF has a variable magnetization direction. The ferromagnetic layer FF is hereinafter referred to as “memory layer FF”.

The magnetization directions of the first pinned layer FP1, the second pinned layer FP2, and the memory layer FF are coplanar. For example, the magnetization direction may lie in a plane parallel to each layer, or may lie in a predetermined plane perpendicular to each layer. In the following, a description is given of the case where the magnetization directions of the first pinned layer FP1, the second pinned layer FP2, and the memory layer FF lie in a plane parallel thereto.

On the other hand, the nonmagnetic layers S1, S2 are made of a nonmagnetic material, and need to be thick enough to isolate the two ferromagnetic layers sandwiching the nonmagnetic layer so that the direct interaction between the two ferromagnetic layers is negligible. At the same time, when a current is passed through the device, it is required that conduction electrons having passed through one magnetic layer reach the other magnetic layer without reversal of the spin direction. Hence the thickness of the nonmagnetic layers S1, S2 is preferably smaller than the spin diffusion length. As a condition for satisfying these requirements, the thickness of the nonmagnetic layers S1, S2 is preferably 0.2 nm to 20 nm. The nonmagnetic layers S1 and S2 are hereinafter referred to as “first intermediate layer S1” and “second intermediate layer S2”, respectively.

Electrodes EL1 and EL2 are coupled to the pinned layers FP1 and FP2, respectively, and an electrode EL3 is coupled to the first intermediate layer S1 The electrodes EL1, EL2, and EL3 are hereinafter referred to as “first electrode EL1”, “second electrode EL2”, and “third electrode EL3”, respectively.

The first intermediate layer S1 and the electrode EL3 may be made of the same material. However, the third electrode EL3 is located distant from the memory layer FF.

A current can be passed between the first electrode EL1 and the third electrode EL3. In addition, a current can be passed at least one of between the first electrode EL1 and the second electrode EL2 and between the second electrode EL2 and the third electrode EL3.

This device can be fabricated by the sputtering and lithography technique, for example.

Next, writing to the memory layer of the magnetic memory device R is described.

When a current larger than a threshold Ic1 is passed in a direction such that electrons flow from the first electrode EL1 toward the third electrode EL3, the magnetization of the memory layer FF is directed parallel to the magnetization of the first pinned layer FP1. That is, the magnetization direction of the memory layer FF takes a first direction when the current is passed with a first polarity so that the current flowing through the first pinned layer FP1 exceeds a first threshold. The first polarity can be a direction such that electrons flow from the first electrode EL1 toward the third electrode EL3 and the first threshold can be the threshold Ic1. Conversely, when a current larger than a threshold Ic2 is passed in a direction such that electrons flow from the third electrode EL3 toward the first electrode EL1, the magnetization of the memory layer FF is directed antiparallel to the magnetization of the first pinned layer FP1. That is, the magnetization direction of the memory layer FF takes a second direction when the current is passed with a second polarity so that the current flowing through the first pinned layer exceeds a second threshold. The second polarity can be a direction such that electrons flow from the third electrode EL3 toward the first electrode EL1 and the second threshold means the threshold Ic2. That is, two different states can be written to the memory layer FF of the magnetic memory device R by introducing currents with different polarities.

In writing, when a current is passed between the first electrode EL1 and the third electrode EL3, there is no need to pass a current to the second electrode EL2 through the memory layer FF and the second intermediate layer S2. For example, at the time of writing, the second electrode EL2 or the terminal of the interconnect coupled thereto may be opened. In the case where the second electrode EL2 or the terminal of the interconnect coupled thereto is grounded or coupled to a power supply terminal at the time of writing, the amount of current flowing to the second electrode EL2 through the memory layer FF and the second intermediate layer S2 depends on the potential of the second electrode EL2 and on the ratio of the electrical resistance of the memory layer FF, the second intermediate layer S2, the second electrode EL2, and the interconnect thereof versus the electrical resistance of the first intermediate layer S1, the third electrode EL3, and the interconnect thereof. Hence, if the second intermediate layer S2 is made of a material having a lower conductivity than the first intermediate layer S1, then, advantageously, the current flowing to the second electrode EL2 through the memory layer FF and the second intermediate layer S2 can be reduced irrespective of the potential of the second electrode EL2, and the power consumption is held down.

However, as described later, at the time of reading, a current needs to be passed between the first electrode EL1 and the second electrode EL2 or between the third electrode EL3 and the second electrode EL2 to detect the electrical resistance therebetween. In order to ensure high reading speed, the material and the thickness need to be adjusted to avoid extremely high resistance. For example, the first intermediate layer S1 can be made of a nonmagnetic metal, and the second intermediate layer S2 can be made of an insulator or semiconductor thin film.

Furthermore, in this invention, the magnetization directions of the first pinned layer FP1 and the memory layer FF are coplanar. Hence there is no need for high-precision control of current flowing through the first electrode EL1 and the third electrode EL3 as in the case of the magnetic memory device described in Patent Document 1, and stable writing can be achieved.

Next, a description is given of reading of a data bit stored as a magnetization direction of the memory layer FF of the magnetic memory device R. Reading can be performed by a method of passing a current between the first electrode EL1 and the second electrode EL2 and a method of passing a current between the second electrode EL2 and the third electrode EL3.

First, the method of reading by passing a current between the first electrode EL1 and the second electrode EL2 is described.

When a current is passed in a direction such that electrons flow from the first electrode EL1 toward the second electrode EL2, or when a current is passed in a direction such that electrons flow from the second electrode EL2 toward the first electrode EL1, electrical resistance depends, by the so-called magnetoresistance effect, on the relative angle between the magnetization direction of the magnetic layer of the memory layer FF and the magnetization direction of the magnetic layer adjacent thereto via the nonmagnetic layer.

If the electrical resistance of the second intermediate layer S2 is higher than the electrical resistance of the first intermediate layer S1 and its interconnect, the electrical resistance variation of the magnetoresistance effect portion composed of the memory layer FF, the second intermediate layer S2, and the second pinned layer FP2 is detected. That is, typically, the electrical resistance decreases if the magnetization direction of the memory layer FF and the magnetization direction of the second pinned layer FP2 are parallel, whereas the electrical resistance increases if they are antiparallel. This is used to read a data bit stored as a magnetization direction of the memory layer FF.

On the other hand, if the electrical resistance of the second intermediate layer S2 is lower than the electrical resistance of the first intermediate layer S1 and its interconnect, the electrical resistance variation of the magnetoresistance effect portion composed of the memory layer FF, the first intermediate layer S1, and the first pinned layer FP1 is detected.

In the case of reading by passing a current between the third electrode EL3 and the second electrode EL2, the electrical resistance variation of the magnetoresistance effect portion composed of the memory layer FF, the second intermediate layer S2, and the second pinned layer FP2 is detected.

In this invention, the magnetization directions of the second pinned layer FP2 and the memory layer FF are coplanar. According to this configuration, the electrical resistance of the magnetoresistance effect portion described above can be efficiently detected.

In this embodiment, the stable magnetization directions of the first pinned layer FP1, the second pinned layer FP2, and the memory layer FF are either parallel or antiparallel to each other. As long as this condition is satisfied, the stable magnetization direction of the first pinned layer FP1, the second pinned layer FP2, and the memory layer FF can be arbitrary. Here, the magnetization direction of these magnetic layers may be either longitudinal or perpendicular to the film plane. The magnetization directions of the first pinned layer FP1 and the second pinned layer FP2 may be either parallel or antiparallel to each other.

Each of the first pinned layer FP1, the second pinned layer FP2, and the memory layer FF can have a multilayer structure including two or more ferromagnetic sublayers and zero or more nonmagnetic sublayers.

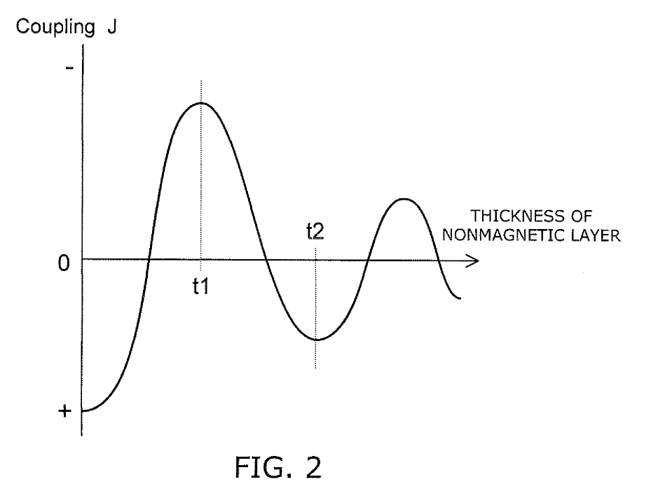

In general, as schematically shown in FIG. 2, exchange coupling between two ferromagnetic layers through a nonmagnetic layer oscillates between positive and negative with respect to the thickness of the nonmagnetic layer. Hence, if the thickness of the nonmagnetic sublayer is set to correspond to any one of the positive (or negative) peak positions in FIG. 2, the exchange coupling between the ferromagnetic sublayers adjacent on both sides thereof can be configured to be ferromagnetic (or antiferromagnetic).

When the first pinned layer FP1 includes two or more ferromagnetic sublayers, each of the ferromagnetic sublayers satisfies the same condition for the magnetization direction as the first pinned layer FP1 made of a monolayer. The magnetization direction of the first pinned layer FP1 refers to the magnetization direction of the ferromagnetic sublayer nearest to the first intermediate layer S1 among the ferromagnetic sublayers included in the first pinned layer FP1.

When the second pinned layer FP2 includes two or more ferromagnetic sublayers, each of the ferromagnetic sublayers satisfies the same condition for the magnetization direction as the second pinned layer FP2 made of a monolayer. The magnetization direction of the second pinned layer FP2 refers to the magnetization direction of the ferromagnetic sublayer nearest to the second intermediate layer S2 among the ferromagnetic sublayers included in the second pinned layer FP2.

When the memory layer FF includes two or more ferromagnetic sublayers, each of the ferromagnetic sublayers satisfies the same condition for the magnetization direction as the memory layer FF made of a monolayer. The magnetization direction of the memory layer FF described with regard to the writing mechanism refers to the magnetization direction of the ferromagnetic sublayer nearest to the first intermediate layer S1 among the ferromagnetic sublayers constituting the memory layer FF. When the electrical resistance of the second intermediate layer S2 is higher than the electrical resistance of the first intermediate layer S1, the magnetization direction of the memory layer FF described with regard to the reading mechanism refers to the magnetization direction of the ferromagnetic sublayer nearest to the second intermediate layer S2 among the ferromagnetic sublayers constituting the memory layer FF. On the other hand, when the electrical resistance of the first intermediate layer S1 is higher than the electrical resistance of the second intermediate layer S2, the magnetization direction of the memory layer FF described with regard to the reading mechanism refers to the magnetization direction of the ferromagnetic sublayer nearest to the first intermediate layer S1 among the ferromagnetic sublayers constituting the memory layer FF.

The magnetization direction of the other ferromagnetic sublayers is uniquely determined because it is determined by whether the exchange coupling between the adjacent ferromagnetic sublayers is ferromagnetic or antiferromagnetic.

Next, the constituent materials of each layer of the above magnetic memory device R are described.

The first pinned layer FP1, the second pinned layer FP2, and the memory layer FF can be made of various magnetic materials such as Co, Fe, Ni, or alloys containing them. When these materials are used, the easy magnetization axis is typically directed in-plane. In the magnetic memory device of this embodiment, a different magnetic material may be used for each layer.

As another example, the first pinned layer FP1, the second pinned layer FP2, and the memory layer FF can be made of materials having a high uniaxial anisotropy constant Ku and exhibiting perpendicular magnetic anisotropy such as FePt, CoPt, FePd, and CoPd. It is also possible to use magnetic materials with the crystal structure being the hcp structure (hexagonal closest packed structure) and exhibiting perpendicular magnetic anisotropy. A typical example thereof is a magnetic material containing metals composed primarily of Co, but other metals having the hcp structure can also be used. It is also possible to use alloys of rare earth elements and iron-group transition elements exhibiting perpendicular magnetic anisotropy such as GdFe, GdCo, GdFeCo, TbFe, TbCo, TbFeCo, GdTbFe, GdTbCo, DyFe, DyCo, and DyFeCo.

In the case where each of the first pinned layer FP1, the second pinned layer FP2, and the memory layer FF has a laminated structure, the constituent ferromagnetic sublayers can be made of Co, and the nonmagnetic sublayers can be made of Pt or Pd.

The thickness of each of the first pinned layer FP1 and the second pinned layer FP2 is preferably in the range of 0.6 nm or more and 100 nm or less. The thickness of the memory layer FF is preferably in the range of 0.2 nm or more and 20 nm or less.

The first pinned layer FP1 is preferably made of materials having high spin polarization because it increases the efficiency of magnetization reversal by spin transfer, decreasing the current threshold. The second pinned layer FP2 is preferably made of materials having high spin polarization because it increases magnetoresistance ratio, facilitating reading. Hence, as the material used for the first pinned layer FP1 and the second pinned layer FP2, the high spin polarization material called “half metal” is a desirable material. Examples of half metals include Heusler alloys, rutile oxides, spinel oxides, perovskite oxides, double perovskite oxides, chromium compounds with zincblende structure, manganese compounds with pyrite structure, and sendust alloys.

Furthermore, these magnetic materials used for the first pinned layer FP1, the second pinned layer FP2, and the memory layer FF can be doped with nonmagnetic elements such as Ag, Cu, Au, Al, Mg, Si, Bi, Ta, B, C, O, N, Pd, Pt, Zr, Ir, W, Mo, Nb, and H to adjust magnetic characteristics and various other material properties including crystallinity and mechanical and chemical characteristics. In the case where the first pinned layer FP1, the second pinned layer FP2, and the memory layer FF have a multilayer structure, the constituent nonmagnetic sublayers can be made of Cu, Au, Ag, Ru, Ir, or Os or alloys containing one or more thereof.

The antiferromagnetic layers AF1, AF2 can be made of Fe—Mn, Pt—Mn, Pt—Cr—Mn, Ni—Mn, Pd—Mn, Pd—Pt—Mn, Ir—Mn, Pt—Ir—Mn, NiO, Fe₂O₃, or magnetic semiconductors. It is noted that the expression “X-Y” used herein, for example, represents an alloy or compound of X and Y. This also applies to the expression in which three or more elements are linked by “−”.

In the case where the first intermediate layer S1, the second intermediate layer S2, the electrode EL1, the electrode EL2, and the electrode EL3 are made of nonmagnetic metals, they can be made of any one of Au, Cu, Cr, Zn, Ga, Nb, Mo, Ru, Pd, Ag, Hf, Ta, W, Pt, and Bi, or alloys containing one or more thereof. The thickness of the first intermediate layer S1 and the second intermediate layer S2 made of such nonmagnetic metals is preferably in the range of 0.2 nm or more to 20 nm or less.

To increase the magnetoresistance effect of the magnetic memory device of this embodiment, it is effective to allow the material of the second intermediate layer S2 to function as a tunnel barrier layer. In this case, the second intermediate layer S2 can be made of Al₂O₃, SiO₂, MgO, AlN, Bi₂O₃, MgF₂, CaF₂, SrTiO₃, AlLaO₃, Al—N—O, Si—N—O, or nonmagnetic semiconductors (ZnO, InMn, GaN, GaAs, TiO₂, Zn, Te, or any one thereof doped with transition metals). These compounds do not need to have exactly stoichiometric compositions, but may have excess or deficiency of oxygen, nitrogen, or fluorine. The thickness of the second intermediate layer S2 made of such an insulating material is preferably 0.2 nm or more and 5 nm or less.

In the case where the second intermediate layer S2 is an insulating layer, it may include pinholes PH inside thereof. In this case, the pinhole PH is filled with the material of at least one of the second pinned layer FP2 and the memory layer FF located on both sides thereof. If the second pinned layer FP2 is coupled with the memory layer FF through pinholes PH, the “BMR effect (ballistic magnetoresistance effect)” due to the so-called “magnetic point contact” occurs. This produces an extremely great magnetoresistance effect and results in an increased margin at the time of reading. A preferable aperture diameter of the pinhole PH is generally 20 nm or less. The pinhole PH can be shaped like a circular cone, circular cylinder, sphere, polygonal cone, polygonal cylinder, or various other configurations. The number of pinholes PH may be either one or more than one.

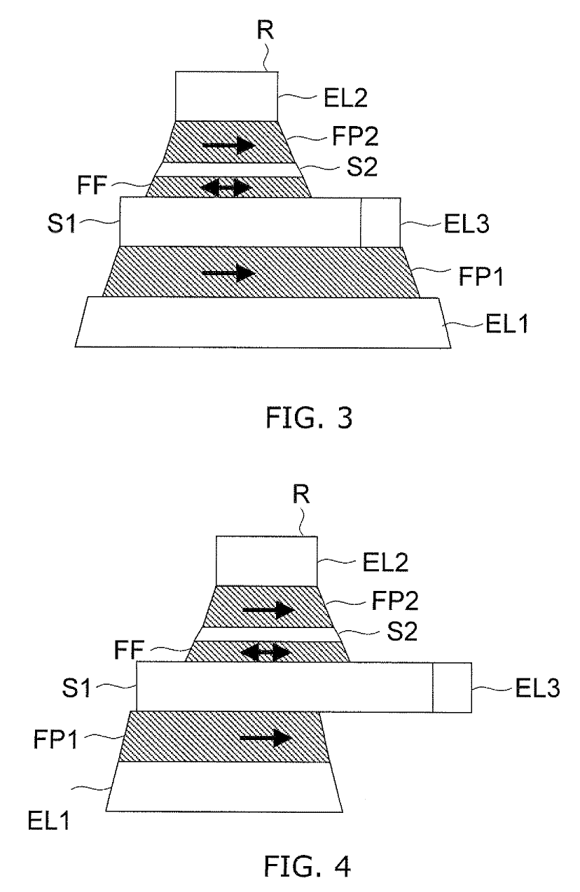

FIGS. 3 to 6 illustrate other embodiments of the invention, i.e., second to fifth embodiments, respectively. The magnetic device of these embodiments can be configured so that the cross-sectional areas of the layers are different from each other.

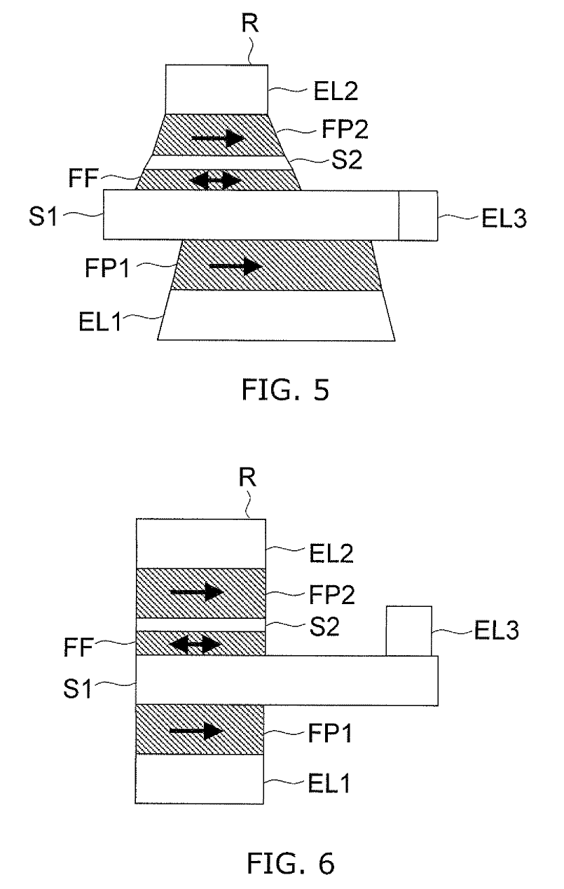

The configuration with the cross-sectional area decreasing toward the top layer as shown in FIG. 3 can be manufactured by patterning each layer after forming all the layers. Alternatively, as shown in FIGS. 4 and 5, the first electrode EL1 and the first pinned layer FP1 can be horizontally shifted with respect to the second electrode EL2 and the second pinned layer FP2.

In this case, the structure shown in FIG. 4, where the first electrode EL1 and the first pinned layer FP1 are located more distant from the third electrode EL3 than the second electrode EL2 and the second pinned layer FP2, is more advantageous than the structure shown in FIG. 5 because the spin accumulation in a region near the interface of the first intermediate layer S1 facing the memory layer FF is greater, which facilitates spin flow in the memory layer FF and increases the writing efficiency.

In the fifth embodiment shown in FIG. 6, the third electrode EL3 can be placed at a position on the upper surface of the first intermediate layer S1 and distant from the memory layer FF. Likewise, although not shown, the third electrode EL3 can be placed at a position on the lower surface of the first intermediate layer S1 and distant from the memory layer FF.

To demonstrate the operation of the embodiments and the effect of the invention, a simulation was performed using the following parameters on the basis of the theoretical models disclosed in Non-Patent Documents 1 and 2.

In this simulation, the following structure A was used as the structure of the first embodiment of the invention, in combination with the following parameters associated with the structure.

Structure A (first embodiment of the invention): Second electrode EL2/Second pinned layer FP2 (magnetic material, thickness 20 nm)/Second intermediate layer S2 (insulator, thickness 0.9 nm)/Memory layer FF (magnetic material, thickness 2.5 nm)/First intermediate layer S1 (nonmagnetic metal, thickness×nm, being varied)/First pinned layer FP1 (magnetic material, thickness 20 nm)/First electrode EL1, shaped like a prism in which the first intermediate layer S1 has a cross-sectional area of 100 nm×200 nm, and the other layers have a cross-sectional area of 50 nm×100 nm, and the third electrode EL3 is coupled to the first intermediate layer S1.

The following structure B was used as a comparative example.

Structure B (comparative example): Shaped like a prism in which all the layers including the above first intermediate layer S1 are 50 nm×100 nm in area, and lacking the third electrode EL3.

With regard to the parameters related to the materials, the electrical resistivity of the nonmagnetic metal was 1.7×10⁻⁸ Ωm, the electrical resistivity of the magnetic material was 6.7×10⁻⁸ Ωm, the spin diffusion length of the nonmagnetic metal was 150 nm, the spin diffusion length of the magnetic material was 20 nm, and the spin polarization in the magnetic material was 0.5.

With regard to the parameters related to the magnetic/nonmagnetic interface, the interface resistance was 5×10⁻⁴ Ωm², the spin polarization was 0.75, and the interface mixing conductance was 0.88 times the conductance. With regard to the parameters related to the magnetic/insulator/magnetic interface, the barrier height was 0.4 eV, and the spin polarization of the incident electrons was 0.5.

In the calculation for the structure B of the comparative example, the threshold of current required for magnetization reversal was determined by estimating the magnitude of torque acting on the magnetization of the memory layer FF upon application of a certain voltage between the first electrode EL1 and the second electrode EL2. Likewise, in the calculation for the structure A of one embodiment of the invention, the threshold of current required for reversal was determined from the magnitude of torque acting on the magnetization of the memory layer FF upon application of a certain voltage between the first electrode EL1 and the third electrode EL3 with the second electrode EL2 being grounded. Here, the value of current refers to the value of current flowing between the first pinned layer FP1 and the first intermediate layer S1.

In an example calculation, when the thickness of the first intermediate layer S1 was 6 nm, the average of the positive and negative reversal current thresholds was 0.3 mA for the structure B of the comparative example and 0.5 mA for the structure A of one embodiment of the invention. Here, in the structure A of this embodiment, when the value of current flowing between the first pinned layer and the intermediate layer S1 was as described above, the value of tunneling current flowing through the second intermediate layer S2 was 0.0003 mA. Thus, in the structure A of this embodiment, the current flowing through the second intermediate layer S2 made of an insulator is 1/1000 of that in the structure B of the comparative example, achieving a significant reduction of power consumption.

Next, the reversal current threshold was calculated for each of the structures A and B with the thickness of the first intermediate layer S1 being varied.

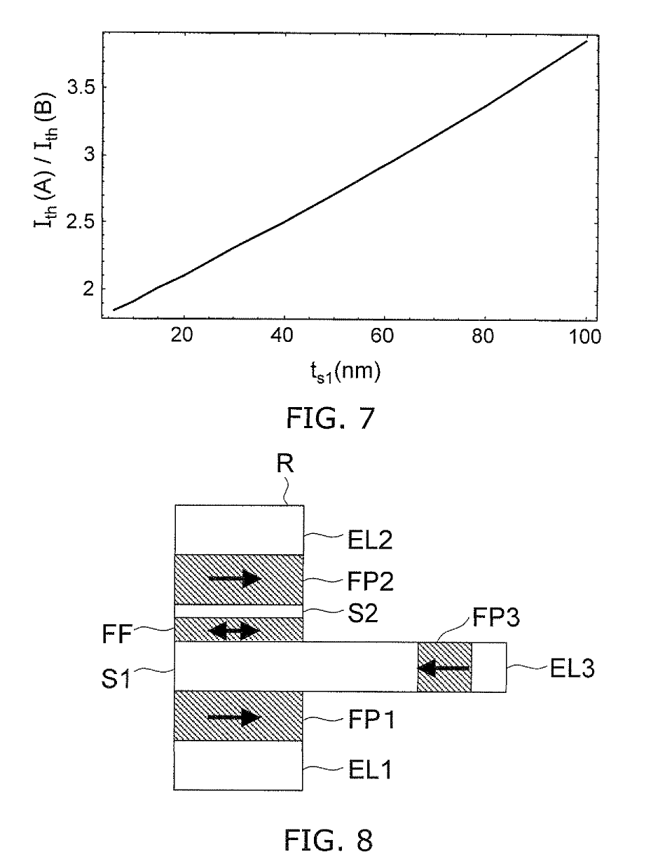

FIG. 7 is a graph showing the reversal current threshold. In FIG. 7, the horizontal axis represents the thickness t_{S1} of the first intermediate layer S1, and the vertical axis represents the ratio of the reversal current threshold of the structure A to the reversal current threshold of the structure B, Iₜₕ(A)/Iₜₕ(B).

As seen from FIG. 7, the increase of the reversal current threshold due to thickening of the first intermediate layer S1 is more significant in the structure A than in the structure B. To avoid possible electromigration, restriction of the reversal current threshold in the structure A to within three times that in the structure B requires that the thickness of the first intermediate layer S1 be 60 nm or less. The restriction thereof to within twice that in the structure B requires that the thickness of the first intermediate layer S1 be 15 nm or less. In practice, the reversal current threshold needs to be restricted to within 2.1 times that in the conventional case. Then the thickness of the first intermediate layer S1 needs to be 20 nm or less.

Next, an example process for manufacturing the magnetic memory device of one embodiment of the invention is described below.

The device described here has the following structure and materials. The numerical value in parentheses represents thickness.

Second electrode EL2 (Cu)/Antiferromagnetic layer AF2 (PtMn: 20 nm)/Second pinned layer FP2 (Fe: 25 nm)/Second intermediate layer S2 (MgO: 0.85 nm)/Memory layer FF (CoFeNi: 3 nm)/First intermediate layer S1 (Cu: 7 nm)/First pinned layer FP1 (CoFe: 10 nm/Ru: 1 nm/CoFe: 10 nm)/Antiferromagnetic layer AF1 (IrMn: 18 nm)/First electrode EL1 (Cu).

The magnetic memory device having the above structure and materials can be manufactured by the following process. First, a first electrode EL1 is formed on the upper surface of a wafer. On the first electrode EL1, an antiferromagnetic layer AF1, a first pinned layer FP1, and a first intermediate layer S1 are laminated using an ultrahigh vacuum sputtering apparatus, and a protective film is formed thereon. Next, a resist is applied onto the protective film and EB (electron beam) exposed to form a mask corresponding to the shape (70 nm×200 nm) of the first intermediate layer S1. Typically, a plurality of openings are provided in the mask, and thereby a plurality of magnetic memory devices corresponding to the openings are formed. Each of the magnetic memory devices is hereinafter referred to as “cell”.

Next, the region not covered with the mask is etched by ion milling. After the etching, the mask is removed. An SiO₂ film is further formed between the cells by ultrahigh vacuum sputtering. Then the surface is smoothed by ion milling to expose the surface of the first intermediate layer S1. Next, a laminated structure composed of a memory layer FF, a second intermediate layer S2, a second pinned layer FP2, and an antiferromagnetic layer AF2 is formed thereon, and a protective film is formed further thereon. The wafer is annealed in a vacuum furnace in magnetic field at 270° C. for 10 hours, for example, to provide the first pinned layer FP1 and the second pinned layer FP2 with unidirectional anisotropy.

Next, a resist is applied onto the protective film and EB exposed to form a mask corresponding to the shape (50 nm×100 nm) of the second pinned layer. Next, the region not covered with the mask is etched by ion milling. After the etching, the mask is removed. An SiO₂ film is further formed between the cells by ultrahigh vacuum sputtering. Then the surface is smoothed by ion milling to expose the surface of the protective film. A second electrode EL2 is formed on this surface of the protective film. Consequently, the magnetic memory device R of the second embodiment shown in FIG. 3 is formed, although in this sample, part of the first intermediate layer S1 is regarded as the electrode EL3.

Next, magnetic memory devices of sixth to eleventh embodiments of the invention are described.

FIG. 8 is a schematic view showing the cross-sectional structure of a magnetic memory device of the sixth embodiment of the invention.

The magnetic memory device R of this embodiment includes, in addition to the device configuration of the first embodiment shown in FIG. 1, a third pinned layer FP3 having a fixed magnetization between the first intermediate layer S1 and the third electrode EL3. The magnetization direction of the third pinned layer FP3 is antiparallel to the magnetization direction of the first pinned layer FP1.

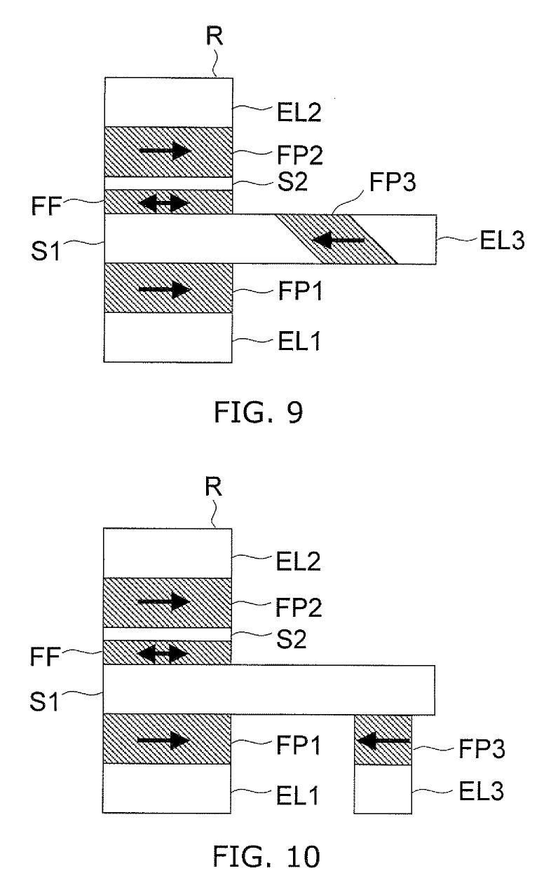

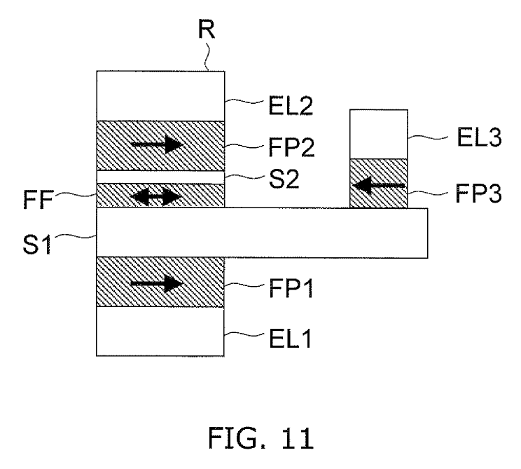

The method for fixing the magnetization of the third pinned layer FP3 is the same as the method for fixing the magnetization of the first pinned layer FP1 and the second pinned layer FP2. The shape and position of the third pinned layer FP3 may be variously selected. The interface between the third pinned layer FP3 and the first intermediate layer does not need to be perpendicular to the film plane. For example, the interface may be inclined as in the seventh embodiment shown in FIG. 9. Furthermore, as in the structure of the eighth embodiment shown in FIG. 10 and the ninth embodiment shown in FIG. 11, the third pinned layer FP3 and the third electrode layer EL3 may be laminated on the lower or upper surface of the first intermediate layer S1.

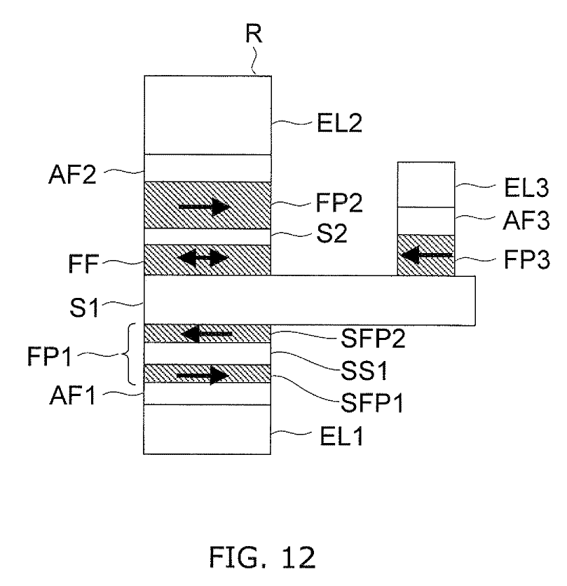

As described previously, in the structure where the third pinned layer FP3 having a fixed magnetization is provided between the first intermediate layer S1 and the third electrode EL3, at least one of the first pinned layer FP1, the second pinned layer FP2, the memory layer FF, and the third pinned layer FP3 may be composed of a plurality of ferromagnetic sublayers and nonmagnetic sublayers. An example of this structure is shown in FIG. 12 as a tenth embodiment. In this embodiment, in the structure where the third pinned layer FP3 and the third electrode layer EL3 are laminated on the upper surface of the first intermediate layer S1, the first pinned layer FP1 is composed of a plurality of ferromagnetic sublayers SFP1 and SFP2 and a nonmagnetic sublayer SS1.

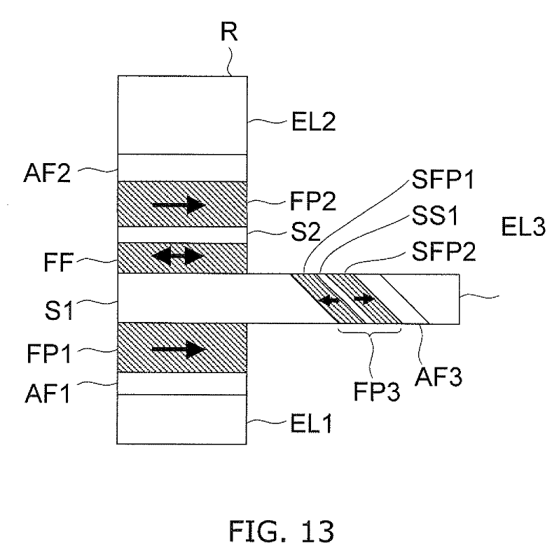

Furthermore, as in the eleventh embodiment shown in FIG. 13, the structure may include a third pinned layer FP3 and a third electrode layer EL3 having an inclined interface, and the third pinned layer FP3 may be composed of a plurality of ferromagnetic sublayers SFP1 and SFP2 and a nonmagnetic sublayer SS1.

In these cases where the third pinned layer is composed of a plurality of ferromagnetic sublayers, the magnetization direction of the third pinned layer FP3 refers to the magnetization direction of the ferromagnetic sublayer nearest to the first intermediate layer S1.

The method of writing to and reading from the memory layer in these embodiments is the same as that in the first embodiment.

Next, the effect of the embodiment is described with reference to an example calculation.

Structure C (ninth embodiment of the invention): The device having the structure shown in FIG. 11 where, in addition to the structure B, a third pinned layer FP3 having a thickness of 20 nm is provided on the upper surface of the first intermediate layer S1. The third pinned layer FP3 has a cross-sectional area of 50 nm×100 nm and is spaced 60 nm from the memory layer FF. The magnetization direction of the third pinned layer FP3 is antiparallel to the magnetization direction of the first pinned layer FP1.

The parameters related to the materials have the values described in the calculation for the structures A and B.

The reversal current threshold was calculated by the same method as the calculation method for the structures A and B. As a result, when the thickness of the first intermediate layer S1 was 6 nm, the reversal current threshold for the structure C was 0.3 mA, which was lower than the reversal current threshold for the structure A, 0.5 mA. This is presumably because the writing efficiency is improved by the effect of electrons reflected at the interface between the first intermediate layer S1 and the third pinned layer FP3. Furthermore, in the structure C, when the value of current flowing between the first pinned layer FP1 and the first intermediate layer S1 was as described above, the value of tunneling current flowing through the second intermediate layer S2 was 0.0002 mA. Thus the magnetic memory device of the structure C according to the ninth embodiment of the invention allows further reduction of power consumption than the above-described structure A according to the first embodiment of the invention.

As described above, in the magnetic memory device of the embodiments, the magnetization directions of the first pinned layer FP1 and the second pinned layer are coplanar, and can be parallel or antiparallel to each other. However, the parallel configuration is more advantageous because annealing in magnetic field can be simultaneously performed in the device manufacturing.

A magnetic memory apparatus can be formed by arranging a large number of magnetic memory devices of the embodiments described above. In the following, embodiments of the magnetic memory apparatus of the invention are described.

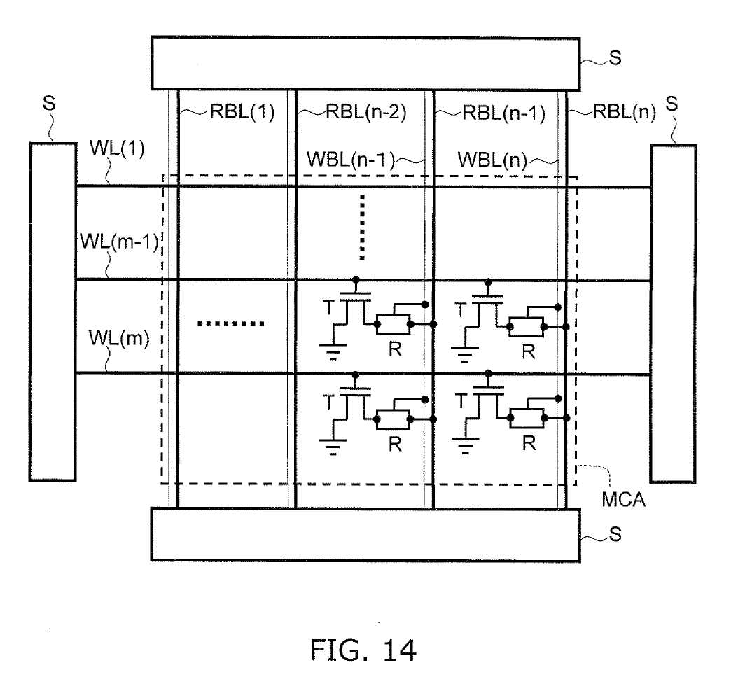

FIG. 14 is a schematic view of a twelfth embodiment of the magnetic memory apparatus of the invention.

More specifically, in the magnetic memory apparatus of this embodiment, a plurality of interconnects WL referred to as word lines are arranged parallel to each other, and in a direction intersecting therewith, a plurality of interconnects WBL referred to as write bit lines are arranged parallel to each other. Furthermore, in parallel to the write bit lines, a plurality of interconnects RBL referred to as read bit lines are arranged parallel to each other. A plurality of memory elements (hereinafter referred to as memory cells), each comprising a switching device T such as a transistor and the magnetic memory device R of the embodiment illustrated above, are arranged in a matrix configuration. One word line WL, one write bit line WBL, and one read bit line RBL are coupled to each memory cell. The word lines WL, the write bit lines WBL, the read bit lines RBL, the switching devices T, and the magnetic memory devices R constitute a memory cell array MCA.

A surrounding circuit S including a decoder for selecting the interconnects and a read circuit is provided outside the memory cell array MCA and coupled to the interconnects. These can be configured by using known techniques. The memory cell array MCA and the surrounding circuit constitute the magnetic memory apparatus.

FIG. 15 shows the connection relationship among the magnetic memory device R, the switching device T, and the associated interconnects in each memory cell of the magnetic memory apparatus of this embodiment. In this embodiment, the first electrode EL1 of the magnetic memory device R constituting the memory cell is coupled to one end of the switching device T, the second electrode EL2 is coupled to the read bit line RBL, the third electrode EL3 is coupled to the write bit line WBL, and the gate portion of the switching device T is coupled to the word line WL.

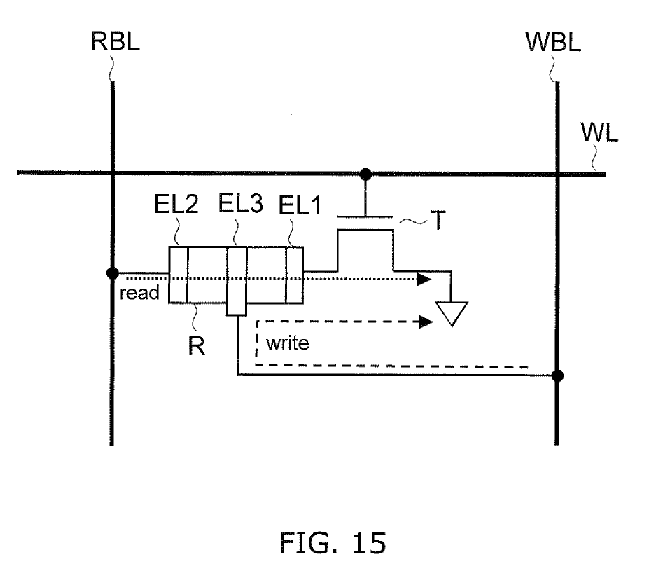

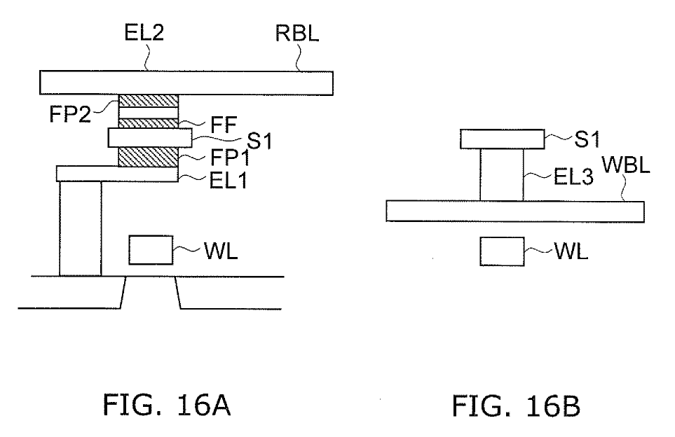

FIGS. 16A and 16B schematically show the cross-sectional structure of the magnetic memory device R, as well as the word line WL, the write bit line WBL, and the read bit line RBL coupled thereto, included in the magnetic memory apparatus of this embodiment. FIGS. 16A and 16B represent different cross sections parallel to each other, where the nonmagnetic layer S1 is commonly shown in the cross-sectional views. While the write bit line WBL is shown below the magnetic memory device R in the cross-sectional view, it may be disposed thereabove. Although not shown, the magnetic memory devices R are electrically insulated from each other by an insulating film I.

Writing to the memory layer FF of the magnetic memory device R begins by selecting an interconnect WL having an address corresponding to an external address signal to turn on the switching device T. Next, writing is performed by passing a current Iw through the write bit line WBL. The conditions imposed on the sign and magnitude of Iw are as illustrated above with regard to the writing operation for the magnetic memory device of the first embodiment.

Reading data stored in the memory layer FF of the magnetic memory device R begins by selecting an interconnect WL having an address corresponding to an external address signal to turn on the switching device T. Next, reading is performed by passing a current Ir through the read bit line RBL. The sign of Ir may be either positive or negative. When Ir is positive, the magnitude of Ir is set to be smaller than the magnitude of the positive write current. When Ir is negative, the magnitude of Ir is set to be smaller than the magnitude of the negative write current.

Next, other embodiments of the magnetic memory apparatus of the invention are described.

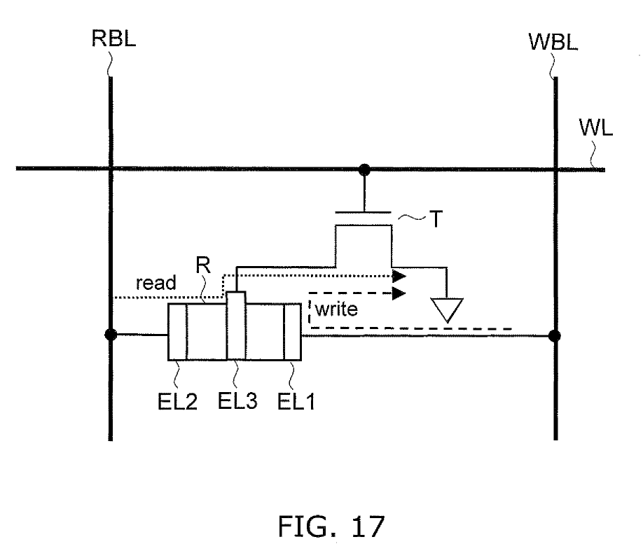

FIG. 17 shows the connection relationship among the magnetic memory device R, the switching device T, and the associated interconnects in each memory cell of a thirteenth embodiment of the magnetic memory apparatus of the invention.

In this embodiment, the first electrode EL1 of the magnetic memory device R constituting the memory cell is coupled to the write bit line WBL, the second electrode EL2 is coupled to the read bit line RBL, the third electrode EL3 is coupled to one end of the switching device T, and the gate portion of the switching device T is coupled to the word line WL.

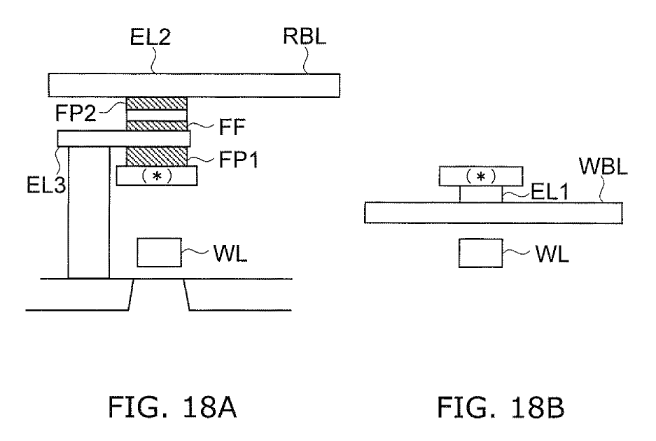

FIGS. 18A and 18B schematically show the cross-sectional structure of the magnetic memory device R, as well as the word line WL, the write bit line WBL, and the read bit line RBL coupled thereto, included in the magnetic memory apparatus of this embodiment. FIGS. 18A and 18B represent different cross sections parallel to each other, where the portions represented by “(*)” in the respective cross-sectional views are coupled to each other. While the write bit line WBL is shown below the magnetic memory device R in the cross-sectional view, it may be disposed thereabove. As described previously, the magnetic memory devices R are electrically insulated from each other by an insulating film I.

The writing and reading method in this embodiment are the same as those in the first embodiment of the magnetic memory apparatus of the invention described above.

Comparison is made between the structures shown in FIGS. 15 and 17. In the structure shown in FIG. 17, as indicated by the dotted line labeled with “read” in FIG. 17, the current path at the time of reading is bent toward the electrode EL3 with respect to the direction perpendicular to the film plane. However, in the structure shown in FIG. 15, as indicated by the dotted line labeled with “read” in FIG. 15, the current path at the time of reading is nearly perpendicular to the film plane. The structure shown in FIG. 15 is characterized in that it has higher reading efficiency than the structure shown in FIG. 17 because conduction electrons moving perpendicular to the film plane contributes to tunneling conduction.

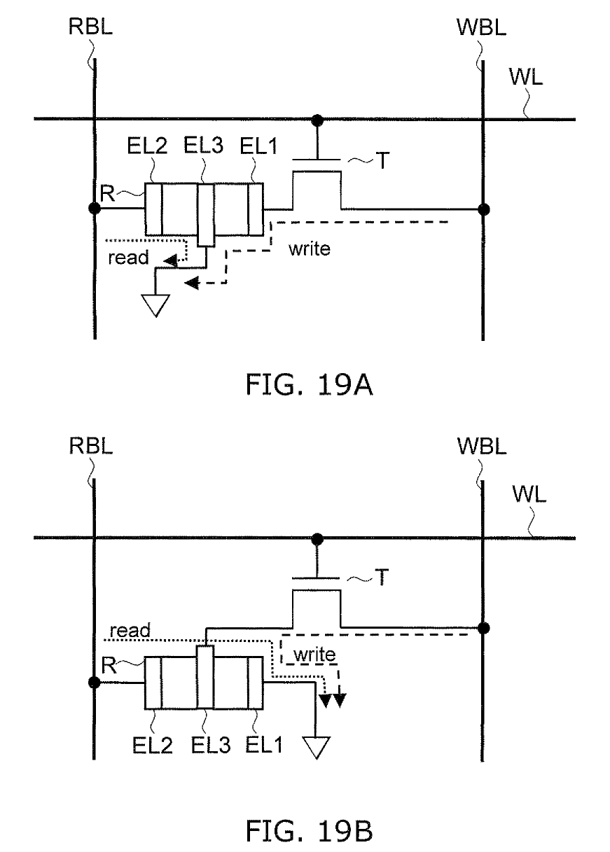

FIGS. 19A and 19B show further embodiments of the magnetic memory apparatus of the invention. In a fourteenth embodiment shown in FIG. 19A, the first electrode EL1 of the magnetic memory device R constituting the memory cell is coupled to one end of the switching device T, the second electrode EL2 is coupled to the read bit line RBL, the third electrode EL3 is grounded, the gate portion of the switching device T is coupled to the word line WL, and another end of the switching device T is coupled to the write bit line WBL.

In the fifteenth embodiment of the magnetic memory apparatus of the invention shown in FIG. 19B, the first electrode EL1 of the magnetic memory device R constituting the memory cell is grounded, the second electrode EL2 is coupled to the read bit line RBL, the third electrode EL3 is coupled to one end of the switching device T, and the gate portion of the switching device T is coupled to the word line WL.

As further illustrative embodiments of the magnetic memory apparatus of the invention, a second write bit line WBL2 can be added to the configuration.

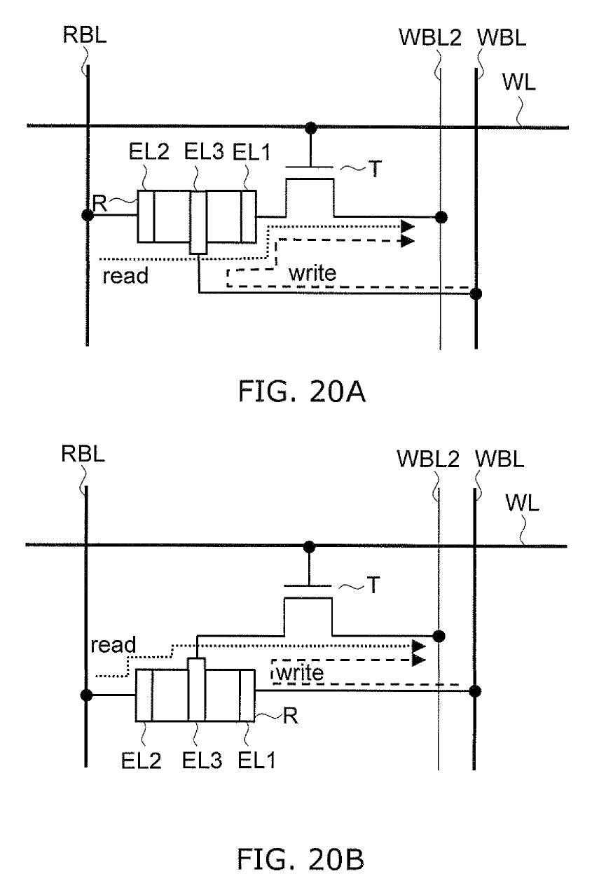

FIGS. 20A and 20B show the connection relationship among the magnetic memory device R, the switching device T, and the associated interconnects in each memory cell of these embodiments. In the magnetic memory apparatus of the sixteenth embodiment illustrated in FIG. 20A, the first electrode EL1 of the magnetic memory device R constituting the memory cell is coupled to one end of the switching device T, the second electrode EL2 is coupled to the read bit line RBL, the third electrode EL3 is coupled to the write bit line WBL, the gate portion of the switching device T is coupled to the word line WL, and another end of the switching device T is coupled to the second write bit line WBL2.

In the magnetic memory apparatus of the seventeenth embodiment illustrated in FIG. 20B, the first electrode EL1 of the magnetic memory device R constituting the memory cell is coupled to the write bit line WBL, the second electrode EL2 is coupled to the read bit line RBL, the third electrode EL3 is coupled to one end of the switching device T, the gate portion of the switching device T is coupled to the word line WL, and another end of the switching device T is coupled to the second write bit line WBL2.

In the present embodiments, at the time of writing, a current is passed through the magnetic memory device R in the direction corresponding to the data bit to be written. For example, in the case of the magnetic memory apparatus of the twelfth and thirteenth embodiment of the invention described above with reference to FIGS. 15 and 17, the write bit line WBL, the magnetic memory device R, and the switching device T are coupled in this order, and another end of the switching device T is grounded or coupled to the power supply terminal. Hence the terminal of WBL is provided with a means operable to apply potentials with two different values or passing currents with different polarities. Likewise, in the case of the magnetic memory apparatus of the fourteenth and fifteenth embodiment of the invention described above with reference to FIGS. 19A and 19B, the write bit line WBL, the switching device T, and the magnetic memory device R are coupled in this order, and the third electrode EL3 or the first electrode EL1 of the magnetic memory device R is grounded or coupled to the power supply terminal. Hence the terminal of WBL is provided is terminated with a means operable to apply potentials with two different values or passing currents with different polarities.

In contrast, in the case of the magnetic memory apparatus of the sixteenth and seventeenth embodiment of the invention described above with reference to FIGS. 20A and 20B, at the time of writing, a current can be passed between WBL and WBL2 to perform writing. That is, in using the apparatus, the direction of current flow can be changed by selecting one of WBL and WBL2 to be coupled to the power supply and grounding the other. Hence, advantageously, the apparatus can be operated by one power supply alone.

In the foregoing description, the magnetization directions of the first pinned layer FP1, the second pinned layer FP2, and the memory layer FF lie in a plane parallel thereto. However, the invention is not limited to this structure. The magnetization directions of the first pinned layer FP1, the second pinned layer FP2, and the memory layer FF can be parallel or antiparallel to each other in the same plane. For example, it is also possible to use a so-called perpendicular magnetization film in which the magnetization directions of the first pinned layer FP1, the second pinned layer FP2, and the memory layer FF are generally perpendicular to the major surface of the layers. Advantageously, in the case of using such a perpendicular magnetization film, the device can be downsized without degrading its thermal fluctuation resistance.

The embodiments of the invention have been described with reference to the examples. However, the invention is not limited to these examples. For instance, any variations in the specific dimensions and material of each component constituting the magnetic memory device and in the shape and material of the electrode, passivation, and insulation structures are encompassed within the scope of the invention as long as those skilled in the art can appropriately select them from known ones to similarly practice the invention and to achieve similar effects.

Furthermore, two or more components of the examples can be combined with each other as long as technically feasible, and such combinations are also encompassed within the scope of the invention as long as they include the features of the invention.

The structures of the magnetic memory device according to the embodiments of the invention shown in FIGS. 1, 3 to 6, 8 to 13 can be vertically reversed.

Each of the antiferromagnetic layers, the intermediate layers, the insulating layers, and other components in the magnetic memory device may be formed as a monolayer, or may have a laminated structure composed of two or more layers.

Any magnetic devices and recording/reproducing apparatuses that can be appropriately adapted and implemented by those skilled in the art on the basis of the magnetic memory devices and magnetic memory apparatuses described above as the embodiments of the invention are also encompassed within the scope of the invention as long as they include the features of the invention.

Other variations and modifications can be conceived by those skilled in the art within the spirit of the invention, and it is understood that such variations and modifications are also encompassed within the scope of the invention.

It is assumed herein that “perpendicular” includes deviations from being exactly perpendicular due to variations occurring in manufacturing processes. Likewise, “parallel”, “horizontal”, and “antiparallel” used herein include deviations from being exactly parallel, horizontal, and antiparallel, respectively.

1. A magnetic memory device comprising:
a first pinned layer including a ferromagnetic material and having a fixed magnetization direction;
a second pinned layer including a ferromagnetic material and having a fixed magnetization direction;
a memory layer provided between the first pinned layer and the second pinned layer, including a ferromagnetic material, and having a variable magnetization direction;
a first intermediate layer provided between the first pinned layer and the memory layer and made of a nonmagnetic material;
a second intermediate layer provided between the second pinned layer and the memory layer and made of a nonmagnetic material;
a first electrode coupled to the first pinned layer;
a second electrode coupled to the second pinned layer; and
a third electrode coupled to the first intermediate layer and not directly coupled to the memory layer,
the magnetization directions of the first pinned layer, the second pinned layer, and the memory layer being parallel or antiparallel to each other,
the magnetization direction of the memory layer taking a first direction when the current is passed with a first polarity so that the current flowing through the first pinned layer exceeds a first threshold, and
the magnetization direction of the memory layer taking a second direction when the current is passed with a second polarity so that the current flowing through the first pinned layer exceeds a second threshold.

2. The device according to claim 1, wherein the magnetization direction of the memory layer can be sensed by passing a current between the first electrode and the second electrode or between the third electrode and the second electrode.

3. The device according to claim 1, wherein the first intermediate layer has a thickness of 0.2 nanometers or more and 20 nanometers or less.

4. The device according to claim 1, wherein the second intermediate layer has a thickness of 0.2 nanometers or more and 5 nanometers or less.

5. The device according to claim 1, wherein the first pinned layer and the second pinned layer have a thickness of 0.6 nanometers or more and 100 nanometers or less.

6. The device according to claim 1, wherein the memory layer has a thickness of 0.2 nanometers or more and 20 nanometers or less.

7. The device according to claim 1, wherein the first electrode and the first pinned layer are shifted in a parallel direction to a surface of the first intermediate layer with respect to the second electrode and the second pinned layer.

8. The device according to claim 7, wherein distances from the third electrode to the first electrode and the first pinned layer are greater than distances from the third electrode to the second electrode and the second pinned layer.

9. The device according to claim 1, wherein the third electrode is placed on at least one of an upper and a lower surfaces of the first intermediate layer and distant from the memory layer.

10. The device according to claim 3, wherein the magnetization direction of the first pinned layer and the magnetization direction of the second pinned layer are parallel to each other.

11. The device according to claim 3, wherein the magnetization directions of the first pinned layer, the second pinned layer, and the memory layer are generally perpendicular to the major surface of the layers.

12. The device according to claim 3, wherein at least one of the first pinned layer, the second pinned layer, and the memory layer is composed of a plurality of ferromagnetic sublayers, or a plurality of ferromagnetic sublayers and one or more nonmagnetic sublayers.

13. The device according to claim 3, further comprising:
an antiferromagnetic layer provided at least one of between the first electrode and the first pinned layer, and between the second electrode and the second pinned layer.

14. The device according to claim 3, wherein the second intermediate layer has a pinhole, which is filled with the material of at least one of the second pinned layer and the memory layer.

15. The device according to claim 3, further comprising:
a third pinned layer provided between the first intermediate layer and the third electrode, including a ferromagnetic material, and having a magnetization direction fixed antiparallel to the magnetization direction of the first pinned layer.

16. The device according to claim 15, wherein at least one of the first pinned layer, the second pinned layer, the memory layer, and the third pinned layer is composed of a plurality of ferromagnetic sublayers, or a plurality of ferromagnetic sublayers and one or more nonmagnetic sublayers.

17. The device according to claim 15, further comprising:
an antiferromagnetic layer provided at least one of between the first electrode and the first pinned layer, between the second electrode and the second pinned layer, and between the third electrode and the third pinned layer.

18. A magnetic memory apparatus comprising:
a plurality of word lines;
a plurality of write bit lines;
a plurality of read bit lines; and
a plurality of magnetic memory devices, each of the magnetic memory devices including;
a first pinned layer including a ferromagnetic material and having a fixed magnetization direction;
a second pinned layer including a ferromagnetic material and having a fixed magnetization direction;
a memory layer provided between the first pinned layer and the second pinned layer, including a ferromagnetic material, and having a variable magnetization direction;
a first intermediate layer provided between the first pinned layer and the memory layer and made of a nonmagnetic material;
a second intermediate layer provided between the second pinned layer and the memory layer and made of a nonmagnetic material;
a first electrode coupled to the first pinned layer;
a second electrode coupled to the second pinned layer; and
a third electrode coupled to the first intermediate layer and not directly coupled to the memory layer,
the magnetization directions of the first pinned layer, the second pinned layer, and the memory layer being parallel or antiparallel to each other,
the magnetization direction of the memory layer taking a first direction when the current is passed with a first polarity so that a current flowing through the first pinned layer to exceeds a first threshold, and
the magnetization direction of the memory layer taking a second direction when the current is passed with a second polarity so that a current flowing through the first pinned layer to exceeds a second threshold,
one of the plurality of word lines and one of the plurality of write bit lines being selected to pass a current between the first electrode and the third electrode of one of the plurality of the magnetic memory devices, thereby allowing the magnetization direction of the memory layer thereof to take one of the first direction and the second direction, and
one of the plurality of word lines and one of the plurality of read bit lines being selected to pass a current between the second electrode and the first electrode of one of the plurality of the magnetic memory devices, or to pass a current between the second electrode and the third electrode thereof, thereby allowing detection of a magnetoresistance effect between the memory layer and the second pinned layer.

19. The apparatus according to claim 18, wherein one of the plurality of word lines and one of the plurality of read bit lines are selected to pass a current between the second electrode and the first electrode of one of the plurality of the magnetic memory devices, thereby allowing detection of a magnetoresistance effect between the memory layer and the second pinned layer.

20. The apparatus according to claim 18, further comprising:
a plurality of second write bit lines,
one of the plurality of word lines and one of the plurality of write bit lines and the plurality of second write bit lines being selected being configured to pass a current between the first electrode and the third electrode of one of the plurality of the magnetic memory devices, thereby allowing the magnetization direction of the memory layer thereof to take one of the first direction and the second direction.
